(19) United States
(12) Patent Application Publication
(10) Pub. No.: US 2008/0157139 A1
(43) Pub. Date: Jul. 3, 2008

(54) IMAGE SENSOR AND METHOD OF MANUFACTURING THE SAME

(76) Inventor: Sang-Gi Lee, Gyeongi-do (KR)

Correspondence Address: SHERR & NOURSE, PLLC, 620 HERNDON PARKWAY, SUITE 200, HERNDON, VA, 20170, US

(21) Appl. No.: 11/869,479

(22) Filed: Oct. 9, 2007

(30) Foreign Application Priority Data
Dec. 27, 2006 (KR) 10-2006-0134814

(51) Int. Cl. H01L 27/146; H01L 31/18

(52) U.S. Cl. 257/292; 257/440; 438/74; 257/E27.133; 257/E27.134

(57) ABSTRACT

An image sensor including a first epitaxial layer having a first photodiode, a second epitaxial layer formed on and/or over the first epitaxial layer, the second epitaxial layer having a second photodiode and a first plug, and a third epitaxial layer formed on and/or over the second epitaxial layer, the third epitaxial layer having a third photodiode, a second plug and an isolation layer.

The present application claims priority under 35 U.S.C. 119 and 35 U.S.C. 365 to Korean Patent Application No. 10-2006-0134814 (filed on Dec. 27, 2006), which is hereby incorporated by reference in its entirety.

### BACKGROUND

An image sensor is a semiconductor device used to convert optical images detected by the image sensor to electric signals. Image sensors may be classified as a charge coupled device (CCD) and a complementary metal oxide semiconductor (CMOS).

A CCD image sensor is provided with metal oxide silicon (MOS) capacitors that are spatially positioned within close proximity to each other and charge carriers are stored in and transferred to the capacitors.

A CMOS image sensor may be provided with a plurality of MOS transistors corresponding to pixels of a semiconductor device having a control circuit and a signal processing circuit as peripheral circuits. The control circuit and the signal processing unit may be integrated together to employ a switching method that detects output through the MOS transistors.

Vertical image sensors structured to have light-receiving regions capable of sensing red, green, and blue colors may be arranged in a vertical direction, thereby realizing an image quality of about three times as high as a horizontal image sensor. The vertical image sensor can also express various colors without a separate color filtering process, so that it can enhance productivity and reduce production cost.

### SUMMARY

Embodiments relate to an image sensor having an improved quality of image.

Embodiments relate to an image sensor including a first epitaxial layer having a first photodiode, a second epitaxial layer formed on and/or over the first epitaxial layer, the second epitaxial layer having a second photodiode and a first plug, and a third epitaxial layer formed on and/or over the second epitaxial layer, third epitaxial layer having a third photodiode, a second plug and an isolation layer. The third photodiode is buried in the third epitaxial layer.

Embodiments relate to an image sensor including a first epitaxial layer formed over a semiconductor substrate; a first photodiode formed in the first epitaxial layer; a second epitaxial layer formed on and/or over the first epitaxial layer; a second photodiode formed in the second epitaxial layer; a first plug formed in the second epitaxial layer; a third epitaxial layer formed on and/or over the second epitaxial layer; a plurality of isolation layers formed on and/or over the third epitaxial layer for separating an isolation region and an active region; a plurality of second plugs formed in the third epitaxial layer adjacent to and in direct contact with a respective one of the plurality of isolation layers; a third photodiode formed in the third epitaxial layer; and a gate structure formed over the third epitaxial layer. In accordance with embodiments, the uppermost surface of the third photodiode is exposed.

Embodiments relate to a method for forming an image sensor including at least one of the following steps: forming a first epitaxial layer on and/or over a semiconductor substrate; forming a first photodiode in the first epitaxial layer; forming a second epitaxial layer on and/or over the first epitaxial layer including the first photodiode; forming a second photodiode in the second epitaxial layer; forming a third epitaxial layer on and/or over the second epitaxial layer including the second photodiode; and burying a third photodiode in the third epitaxial layer.

### DRAWINGS

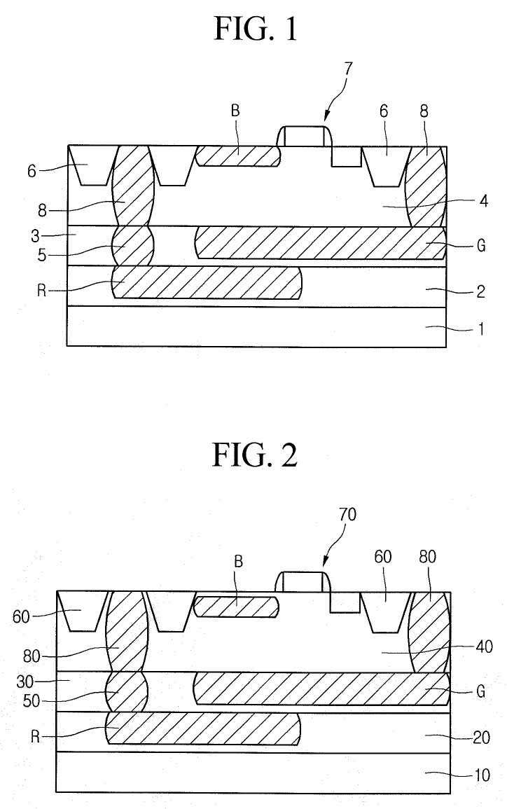

Example FIGS. 1 to 7 illustrate a vertical image sensor, in accordance with embodiments.

### DESCRIPTION

Further, in the description of the embodiment, it will be understood that, when a layer (or film), a region, a pattern, or a structure is referred to as being “on (above/over/upper)” or “under (below/down/lower)” another substrate, another layer (or film), another region, another pad, or another pattern, it can be directly on the other substrate, layer (or film), region, pad, or pattern, or one or more intervening layers may also be present. Furthermore, it will be understood that, when a layer (or film), a region, a pattern, a pad, or a structure is referred to as being “between” two layers (or films), regions, pads, or patterns, it can be the only layer between the two layers (or films), regions, pads, or patterns, or one or more intervening layers may also be present. Thus, it should be determined by technical idea of the invention.

As illustrated in example FIG. 1, a vertical image sensor in accordance with embodiments can include first epitaxial layer 2 is formed on and/or over semiconductor substrate 1. Semiconductor substrate 1 can be a P-type semiconductor substrate. N-type impurity ions such as arsenic (As) ions can be implanted into first epitaxial layer 2, thereby forming red photodiode R Subsequently, boron ions can be implanted between the red photodiodes, thereby forming an insulating region.

Second epitaxial layer 3 can be formed on and/or over first epitaxial layer 2, and then N-type impurity ions such as arsenic can be can be implanted into second epitaxial layer 3, thereby forming green photodiode G. Subsequently, the boron ions can be implanted between the green photodiodes, thereby forming an insulating region. High-energy ions can be implanted into second epitaxial layer 3, thereby forming first plug 5.

Third epitaxial layer 4 can be formed on and/or over second epitaxial layer 3. Isolation layer 6 for separating an isolation region and an active region can be formed on and/or over third epitaxial layer 3. Isolation layer 6 can be formed using a shallow trench isolation (STI) process.

Subsequently, gate structure 7 can be formed on and/or over third epitaxial layer 4. N-type impurity ions such as arsenic can be implanted in third epitaxial layer 4, thereby forming blue photodiode B. High-energy ions can be implanted into third epitaxial layer 4, thereby forming second plug 8.

In the vertical image sensor manufactured in accordance with embodiments, blue photodiode B can be formed on and/or over the surface of third epitaxial layer 4 in order to receive light having a short wavelength. Accordingly, the uppermost surface of blue photodiode B can be exposed and not covered by third epitaxial layer 4.

Testing conducted on the vertical image sensor manufactured in accordance with embodiments to determine how much influence blue photodiode B has on image quality, i.e., the precision of an output image. Consequently, leakage current can be increased due to blue photodiode B, and thus, image quality can be lowered.

Moreover, the image sensor manufactured in accordance with embodiments can be arranged such that second plug 8 can be formed laterally in contact with or adjacent to isolation layer 6.

The effect of the lateral spatial proximity or distance between second plug 8 and isolation layer 6 has on image quality can be analyzed through testing. In a first test, the lateral spatial distance between second plug 8 and isolation layer 6 is 0.08 μm. In a second test, the lateral spatial distance between second plug 8 and isolation layer 6 is 1.10 μm. In accordance with the tests, it was discovered that as the lateral spatial distance becomes small, the leakage current by isolation layer 6 is increased, and thus, image quality is lowered.

As illustrated in example FIG. 2, first epitaxial layer 20 can be formed on and/or over semiconductor substrate 10. N-type impurity ions such as arsenic (As) ions, can be implanted into first epitaxial layer 20, thereby forming red photodiode R. Semiconductor substrate 10 can be a P-type semiconductor substrate into which P-type impurity ions are implanted.

Second epitaxial layer 30 can be formed on and/or over first epitaxial layer 20. N-type impurity ions such as arsenic (As) ions can be implanted into second epitaxial layer 30, thereby forming green photodiode G. First plug 50 can be formed to extend substantially vertically through second epitaxial layer 30.

Third epitaxial layer 40 can be formed on and/or over second epitaxial layer 30. A plurality of isolation layers 60 for separating an isolation region and an active region can be formed in third epitaxial layer 40. Isolation layers 60 can be formed as shallow trench isolation (STI) layers. Blue photodiode B and a plurality of second plugs 80 can be formed on and/or over the active region excluding isolation layer 60. Second plugs 80 can be formed to extend vertically through third epitaxial layer 40. Blue photodiode B can be formed in third epitaxial layer 40 between gate structure 70 and isolation layer 60. Second plug 80 can be electrically connected to first plug 50. Gate structure 70 may include an oxide layer and doped polysilicon formed on and/or over third epitaxial layer 40.

Blue photodiode B can be buried in third epitaxial layer 40 without having its uppermost surface being exposed. Blue photodiode B can be buried in third epitaxial layer 40 at a depth of between approximately 0.010 μm to 0.200 μm. Blue photodiode B can be buried at a depth of approximately 0.08 μm from the uppermost surface of third epitaxial layer 40.

Second plug 80 can be formed in third epitaxial layer 40. Second plug 80 can be laterally spaced a predetermined distance from isolation layer 60. Second plug 80 can be laterally spaced from isolation layer 60 by at least approximately 0.08 μm. Second plug 80 can be laterally spaced from isolation layer 60 by approximately 1.10 μm.

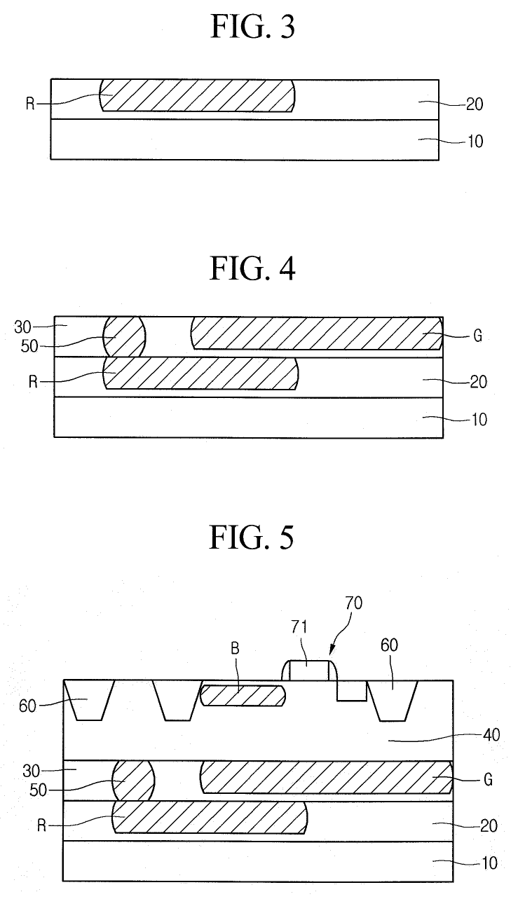

As illustrated in example FIG. 3, first epitaxial layer 20 is formed on semiconductor substrate 10, such as a P-type, semiconductor substrate. N-type impurity ions such as arsenic (As) ions can then be implanted into first epitaxial layer 20, thereby forming red photodiode R. Subsequently, boron ions can be implanted between red photodiode R, thereby forming an insulating region.

As illustrated in example FIG. 4, second epitaxial layer 30 can be formed on and/or over first epitaxial layer 20. N-type impurity ions can then be implanted into second epitaxial layer 30, thereby forming green photodiode G. Subsequently, boron ions can be implanted between the green photodiodes G, thereby forming an insulating region. Then, high-energy ions can be implanted into second epitaxial layer 30, thereby forming first plug 50 extending through second epitaxial later 30.

As illustrated in example FIG. 5, third epitaxial layer 40 can be formed on and/or over second epitaxial layer 30. An isolation region forming process for separating an isolation region and an active region can be performed on and/or over third epitaxial layer 40, thereby forming a plurality of isolation layers 60. Isolation layers 60 can be formed using an STI process. Subsequently, an oxide layer can be formed and doped polysilicon 71 can be deposited can be the oxide layer. A photolithographic process can be performed to form gate structure 70 having the oxide layer and polysilicon 71 left by etching. Subsequently, N-type impurity ions can be implanted on and/or over the uppermost surface of third epitaxial layer 40, thereby forming blue photodiode B thereon.

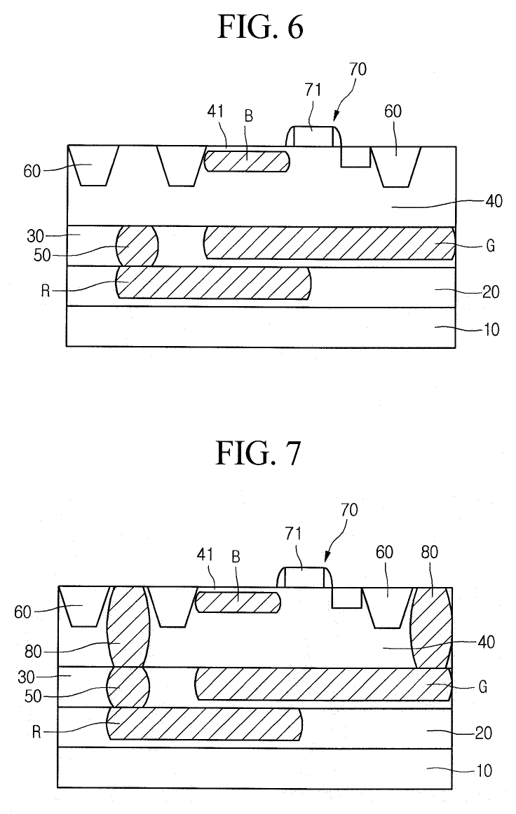

As illustrated in example FIG. 6, P-type impurity ions can be implanted into the surface of third epitaxial layer 40, thereby forming a P-type cover layer 41 on and/or over blue photodiode B. Consequently, blue photodiode B is buried under the uppermost surface of third epitaxial layer 40.

P-type cover layer 41 can be formed to have a thickness of between approximately 0.010 μm to 0.200 μm from the surface of third epitaxial layer 40. P-type cover layer 41 can be formed to have a thickness thickness of approximately 0.08 μm from the uppermost surface of third epitaxial layer 40.

Blue photodiode B can be formed to have a thickness of between approximately 0.010 μm to 0.200 μm from the uppermost surface of third epitaxial layer 40 by implanting N-type impurity ions having high energy. Blue photodiode B can be formed at a thickness of approximately 0.08 μm from the uppermost surface of third epitaxial layer 40.

As illustrated in example FIG. 7, high-energy ions can be implanted into third epitaxial layer 40 using a mask covering isolation layer 60 and a part of its surrounding region as an ion implantation mask, thereby forming second plug 80 adjacent to isolation layer 60. The mask can use one greater than an edge of isolation layer 60 by approximately 0.08 μm or more. In accordance with embodiments, a mask greater than by approximately 1.10 μm can be used.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a first epitaxial layer having a first photodiode formed over a semiconductor substrate;
a second epitaxial layer formed over the first epitaxial layer, the second epitaxial layer having a second photodiode and a first plug; and
a third epitaxial layer formed over the second epitaxial layer, the third epitaxial layer having a third photodiode, a second plug and an isolation layer,
wherein the third photodiode is buried in the third epitaxial layer.

2. The apparatus of claim 1, wherein the second plug is laterally spaced from the isolation layer.

3. The apparatus of claim 1, wherein the third photodiode has a thickness of about 0.010 μm to 0.200 μm when measured from an uppermost surface of the third epitaxial layer.

4. The apparatus of claim 2, wherein the second plug is laterally spaced from the isolation layer by a distance of at least about 0.08 μm.

5. The apparatus of claim 2, wherein the second plug is laterally spaced from the isolation layer by a distance of approximately 1.10 μm.

6. The apparatus of claim 1, wherein the third photodiode comprises a blue photodiode.

7. The apparatus of claim 1, further comprising a cover layer formed over the third photodiode.

8. The apparatus of claim 7, wherein the cover layer is formed by implanting P-type impurity ions into the third epitaxial layer.

9. The apparatus of claim 8, wherein thickness of the cover layer is between approximately 0.010 μm to 0.200 μm.

10. The apparatus of claim 8, wherein thickness of the cover layer is approximately 0.08 μm.

11. An apparatus comprising:
a first epitaxial layer formed over a semiconductor substrate.
a first photodiode formed in the first epitaxial layer;
a second epitaxial layer formed over the first epitaxial layer;
a second photodiode formed in the second epitaxial layer;
a first plug formed in the second epitaxial layer;
a third epitaxial layer formed over the second epitaxial layer;
a plurality of isolation layers formed over the third epitaxial layer for separating an isolation region and an active region;
a plurality of second plugs formed in the third epitaxial layer adjacent to and in direct contact with a respective one of the plurality of isolation layers;
a third photodiode formed in the third epitaxial layer; and
a gate structure formed over the third epitaxial layer,
wherein the uppermost surface of the third photodiode is exposed.

12. The apparatus of claim 11, wherein the semiconductor substrate comprises a P-type semiconductor substrate.

13. The apparatus of claim 11, wherein conductive impurity ions are implanted into the first epitaxial layer to form the first photodiode, the second epitaxial layer to form the second photodiode, and the third epitaxial layer to form the third photodiode.

14. The apparatus of claim 13, wherein the conductive impurity ions comprises N-type impurity ions.

15. The apparatus of claim 14, wherein the N-type impurity ions comprises arsenic.

16. The apparatus of claim 15, wherein the first photodiode comprises a red photodiode, the second photodiode comprises a green photodiode and the third photodiode comprises a blue photodiode.

17. The apparatus of claim 16, wherein the blue photodiode is formed between the gate structure and one of the plurality of isolation layers.

18. The apparatus of claim 17, wherein at least portions of the red photodiode, the green photodiode and the blue photodiode are aligned on a same vertical line.

19. The apparatus of claim 11, wherein high-energy ions are implanted into the second epitaxial layer to for the first plug and the third epitaxial layer to form the plurality of second plugs.

20. A method for forming an image sensor, the method comprising the steps of:
forming a first epitaxial layer over a semiconductor substrate;
forming a first photodiode in the first epitaxial layer;
forming a second epitaxial layer over the first epitaxial layer and the first photodiode;
forming a second photodiode in the second epitaxial layer;
forming a third epitaxial layer over the second epitaxial layer and the second photodiode; and
burying a third photodiode in the third epitaxial layer.
